(19) United States
(12) Patent Application Publication
(10) Pub. No.: US 2025/0212372 A1
(43) Pub. Date: Jun. 26, 2025

(54) POWER SUPPLY UNIT WITH IMPROVED SPACE UTILIZATION AND HEAT DISSIPATION

(71) Applicant: PANJIT INTERNATIONAL INC., KAOHSIUNG CITY (TW)

(72) Inventors: CHIEN-CHUN WANG, TAINAN CITY (TW); CHE FANG, KAOHSIUNG CITY (TW); CHI-HSUEH LI, TAINAN CITY (TW); CHUNG-HSIUNG HO, KAOHSIUNG CITY (TW)

(21) Appl. No.: 18/418,507

(22) Filed: Jan. 22, 2024

(30) Foreign Application Priority Data
Dec. 20, 2023 (TW) 112213949

(51) Int. Cl. H05K 7/20; H05K 1/18

(52) U.S. Cl. CPC H05K 7/209; H05K 1/181; H05K 7/20445; H05K 7/20909; H05K 2201/10015; H05K 2201/10022; H05K 2201/1003; H05K 2201/10166; H05K 2201/10174; H05K 2201/10545

(57) ABSTRACT

A power supply unit with improved space utilization and heat dissipation, including a heat-dissipation case, a circuit board and a plurality of electronic components; the circuit board is disposed in the heat-dissipation case, and has a first deployment surface and a second deployment surface in opposite positions; the plurality of electronic components include at least one power component and other electronic components, wherein the other electronic components are disposed on the first deployment surface of the circuit board, and the at least one power component is disposed on the second deployment surface of the circuit board and connects to an inner surface of the heat-dissipation case.

### CROSS REFERENCE TO RELATED APPLICATION(S)

This application claims the priority to patent application No. 112213949 filed in Taiwan on Dec. 20, 2023, which is hereby incorporated in its entirety by reference into the present application.

### BACKGROUND OF THE INVENTION

### 1. Field of the Invention

The present invention relates to a power supply unit, in particular to a power supply unit with improved space utilization and heat dissipation.

### 2. Description of the Related Art

The main function of a power supply unit is to receive an input power source, convert the input power source into a stable DC power source which is subsequently supplied to a motherboard, and control circuits or other loads of an electronic device.

Please refer to FIG. 9. It is known that the power supply unit 80 includes a case 81 and a circuit board 82 disposed in the case 81. A top surface of the circuit board 82 is disposed with a plurality of electronic components 83. These electronic components 83 constitute a circuit board with functions such as rectification, transformer, voltage stabilization, and power conditioning. It should be noted that FIG. 9 only schematically shows the layout of electronic components 83 on the circuit board 82, and these electronic components 83 may include, for example, capacitors 830, a rectifier 831 and a transformer 832.

However, the space for placing electronic components 83 on the top surface of the circuit board 82 is quite limited, and in such a space-limited environment, layout of these electronic components 83 is restricted. For example, the transformer 832 cannot be easily changed to another transformer of a larger size, thus failing to meet certain customized needs; or the rectifier 831 needs to have a heat sink 8310 for certain heat dissipation requirements, but due to space constraints, it is not possible to provide a larger sized heat sink or cooling fins for the rectifier 83; as a result, the heat dissipation cannot be further improved.

### SUMMARY OF THE INVENTION

In view of the above-mentioned issues, the main purpose of the present invention is to provide a power supply unit with improved space utilization and heat dissipation in order to overcome the problems of limited layout of electronic components and heat dissipation caused by limited space on the top surface of the circuit board where electronic components are disposed in the prior art power supply unit.

A power supply unit with improved space utilization and heat dissipation of the present invention includes:
a heat-dissipation case;
a circuit board, disposed in the heat-dissipation case and having a first deployment surface and a second deployment surface located in opposite positions; and
a plurality of electronic components including at least one power component and other electronic components, wherein the other electronic components are disposed on the first deployment surface of the circuit board, and the at least one power component is disposed on the second deployment surface of the circuit board and connected to an inner surface of the heat-dissipation case.

According to the structure of the power supply unit with improved space utilization and heat dissipation of the present invention, not all electronic components of the present invention are disposed on the same side of the circuit board, but at least one power component is disposed on the second deployment surface of the circuit board, while other electronic components are located on the first deployment surface of the circuit board, so that the first deployment surface of the circuit board has more space available to be utilized to achieve improved space utilization effects. Furthermore, since each said power component is connected to the heat-dissipation case having a heat dissipation function, the heat generated by each said power component during operation can be conducted to the heat-dissipation case to be dissipated, thereby effectively enhancing the heat dissipation effect.

In order to make the above objects, features and advantages of the present invention more apparent and easier to understand, the following embodiments, together with the accompanying drawings, are described in detail as follows.

### BRIEF DESCRIPTION OF THE DRAWINGS

FIG. 1 shows a three-dimensional (3D) schematic view of an embodiment of a power supply unit of the present invention;

FIG. 2 shows a cross-sectional schematic diagram of an embodiment of the power supply unit of the present invention;

FIG. 3 shows a partially enlarged cross-sectional schematic diagram of an embodiment of the power supply unit of the present invention;

FIG. 4 shows a partially enlarged cross-sectional schematic diagram of an embodiment of the power supply unit of the present invention;

FIG. 5 shows a partially enlarged cross-sectional schematic diagram of an embodiment of the power supply unit of the present invention;

FIG. 6 shows a partially enlarged cross-sectional schematic diagram of an embodiment of the power supply unit of the present invention;

FIG. 7 shows a partially enlarged cross-sectional schematic diagram of an embodiment of the power supply unit of the present invention;

FIG. 8 shows a 3D schematic view of an embodiment of the power supply unit of the present invention; and

FIG. 9 shows a 3D schematic view of a conventional power supply unit.

### DETAILED DESCRIPTION OF THE INVENTION

The technical contents, features and effects of the present invention will be clearly presented in the following detailed description of the preferred embodiment with reference to the drawings. In addition, the directional terms mentioned in the following embodiments, such as: up, down, left, right, front, back, bottom, top, etc., are only relative directions with reference to the drawings, and do not represent absolute directional positions; therefore, the directional terms used are for the convenience of illustrating their relative positional relationships, and are not intended to impose limitations on the present invention.

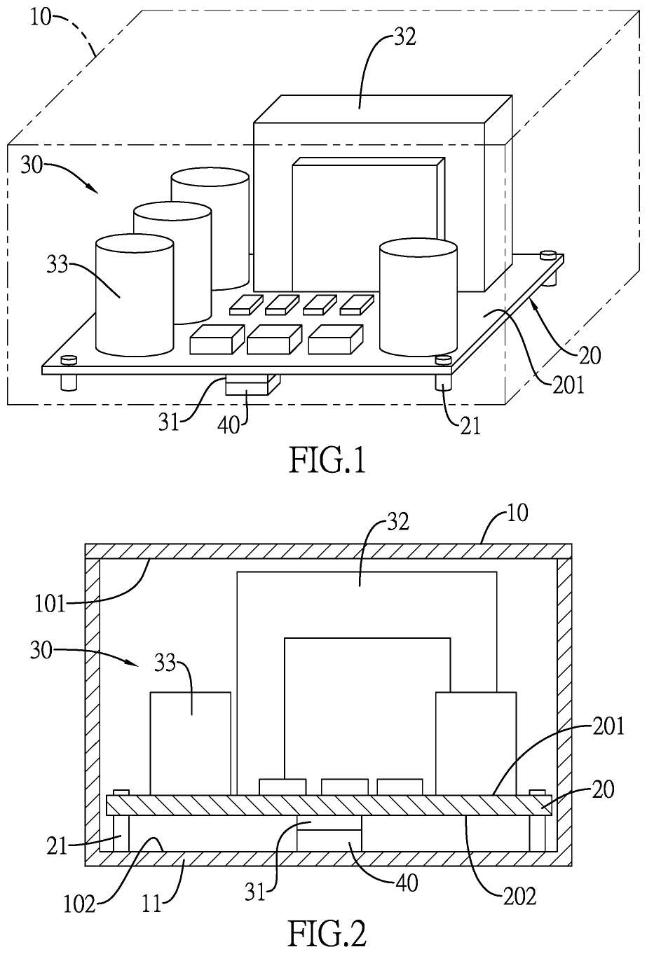

Please refer to FIGS. 1 and 2: an embodiment of the power supply unit with improved space utilization and heat dissipation of the present invention includes a heat-dissipation case 10, a circuit board 20 and a plurality of electronic components 30. The circuit board 20 is disposed in the heat-dissipation case 10, and the electronic components 30 are disposed on the circuit board 20, i.e., the circuit board 20 and the electronic components 30 are both located in the heat-dissipation case 10.

The heat-dissipation case 10 can be made of metal, so that the heat-dissipation case 10 can have a specific heat dissipation effect through thermal conductivity of the metal. For example, the heat-dissipation case 10 can be made of iron or aluminum, but not limited to iron and aluminum. The circuit board 20 has a first deployment surface 201 and a second deployment surface 202 respectively located in opposite positions. Taking FIG. 2 as an example, a top surface and a bottom surface of the circuit board 20 can be defined as the first deployment surface 201 and the second deployment surface 202 respectively. A distance between the first deployment surface 201 and an inner top plate surface 101 of the heat-dissipation case 10 can be greater than a distance between the second deployment surface 202 and an inner bottom plate surface 102 of the heat-dissipation case 10, i.e., the circuit board 20 divides an inner space of the heat-dissipation case 10 into two sub-spaces, the upper and lower sub-spaces. Among them, a structure that the circuit board 20 is fixed in the heat-dissipation case 10 is common knowledge in the pertained technical field, for example, the circuit board 20 may be fixed and elevated on the bottom plate 11 of the heat-dissipation case 10 by means of feet 21, but not limited to using the feet 21 to fix the circuit board 20 on the bottom plate 11 of the heat-dissipation case 10, and it will suffice as long as the circuit board 20 is fixed in the heat-dissipation case 10.

These electronic components 30 constitute a power supply circuit with functions such as rectification, transformer, voltage stabilization, and power regulation. It should be noted that detailed circuit structures of the power supply circuit itself are not targeted technical features of the present invention, and therefore such detailed circuit structures are not described herein. The electronic components 30 include at least one power component 31 and other electronic components 30 other than the at least one power component 31. The at least one power component 31 refers to the one with a higher or highest operating temperature among the electronic components 30, i.e., the operating temperature of the at least one power component 31 is higher than those of the other electronic components 30. The other electronic components 30 are disposed on the first deployment surface 201 of the circuit board 20. The other electronic components 30 may be, for example, a transformer 32, a capacitor 33, an inductor, a resistor, an integrated circuit component, a packaging component and/or a fuse, but are not limited to the components listed above. The at least one power component 31 is disposed on the second deployment surface 202 of the circuit board 20. The at least one power component 31 can be, for example, a bridge rectifier, a rectifier diode, an insulated gate bipolar transistor (IGBT), a metal oxide semiconductor field effect transistor (MOSFET), integrated circuit components and/or packaging components, but are not limited to the components listed above. The number of the at least one power component 31 may be one or more, and a surface mount device (SMD) packaging type may be a preferred component type of each said power component 31.

The at least one power component 31 can be connected to an inner surface of the heat-dissipation case 10 facing the second deployment surface 202. The inner surface can be the inner bottom plate surface 102 as mentioned above, wherein each said power component 31 can be in direct contact with the inner bottom plate surface 102 of the heat-dissipation case 10 to connect to the heat-dissipation case 10, or as shown in FIGS. 1 and 2, each said power component 31 can be connected to the inner bottom plate surface 102 of the heat-dissipation case 10 through a thermal conductive member 40, and a size of the thermal conductive member 40 may be larger than or equal to a size of each said power component 31.

The first embodiment of the thermal conductive member 40 may be a thermal interface material layer (TIM) or a metal block connected between each said power component 31 and the heat-dissipation case 10. For example, the thermal interface material layer can be thermal glue, thermal paste or a thermal gap pad (TGP), where the thermal gap pad can be, for example, a silicone sheet. The metal block may be, for example, an aluminum block, wherein the thermal conductive glue or thermal paste may be disposed between each said power component 31 and the metal block, and may be disposed between the metal block and the inner bottom plate surface 102 of the heat-dissipation case 10.

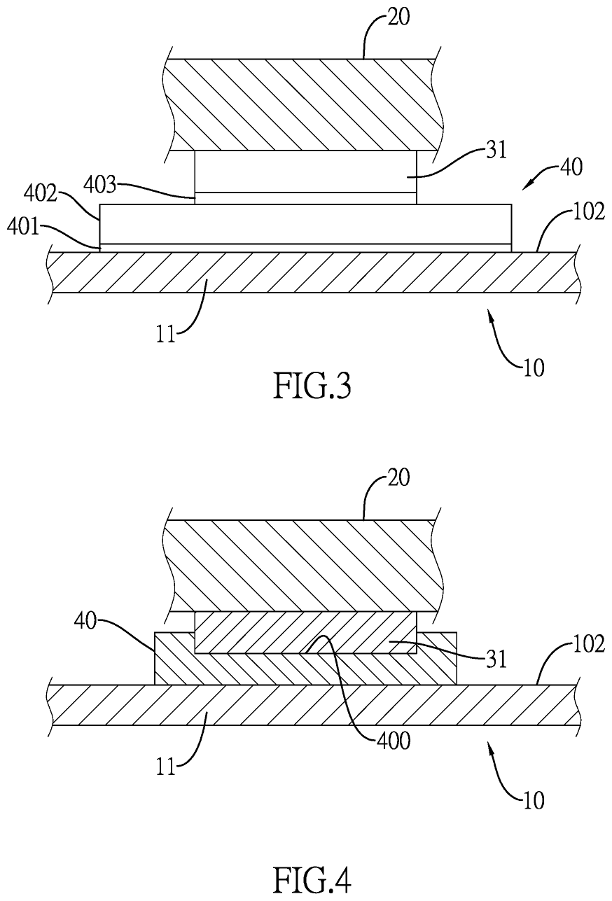

A second embodiment of the thermal conductive member 40 can be a composite layer, which may be a composite structure formed by stacking at least two of the aforementioned heat-conducting pad, metal block, metal sheet and cooling fins (heat sink), said heat-conducting pad, metal block, metal sheet and cooling fins are stacked in a staggered manner, and each can be arranged in more than one layer respectively, wherein the metal sheet can be, for example, an aluminum (Al) sheet, but not limited to the aluminum sheet. Please refer to the embodiment of FIG. 3. The thermal conductive member 40 includes a first heat-conducting pad 401, a cooling fin 402 and a second heat-conducting pad 403 that are sequentially stacked in a staggered manner. The first heat-conducting pad 401 of the thermal conductive member 40 is disposed on the inner bottom plate surface 102 of the heat-dissipation case 10, and the second heat-conducting pad 403 of the thermal conductive member 40 is connected with the surface of each said power component 31.

In the foregoing embodiment, the surface (i.e., the bottom surface) of each said power component 31 is in flat-contact against the surface (i.e., the top surface) of the thermal conductive member 40. Please refer to another embodiment shown in FIG. 4. The power component 31 can be embedded into a top of the thermal conductive member 40, so that the bottom surface and part of the side periphery of each said power component 31 are connected to the thermal conductive member 40. This can increase contact area between each said power component 31 and the thermal conductive member 40 compared with the flat-contact manner; as a result, thermal conductivity and heat dissipation effects are improved. For example, when the contact part between the thermal conductive member 40 and each said power component 31 is a hard object, such as a metal block or cooling fins, the thermal conductive member 40 can form a notch 400 to imbed and accommodate the bottom surface and part of the side periphery of the power component 31, and thermal conductive glue or thermal paste may be disposed between each said power component 31 and the notches 400 of the thermal conductive member 40. In contrast, when the thermal conductive member 40 is a soft object, such as thermal conductive glue, thermal paste or silicone sheet, each said power component 31 can be directly embedded in the thermal conductive member 40.

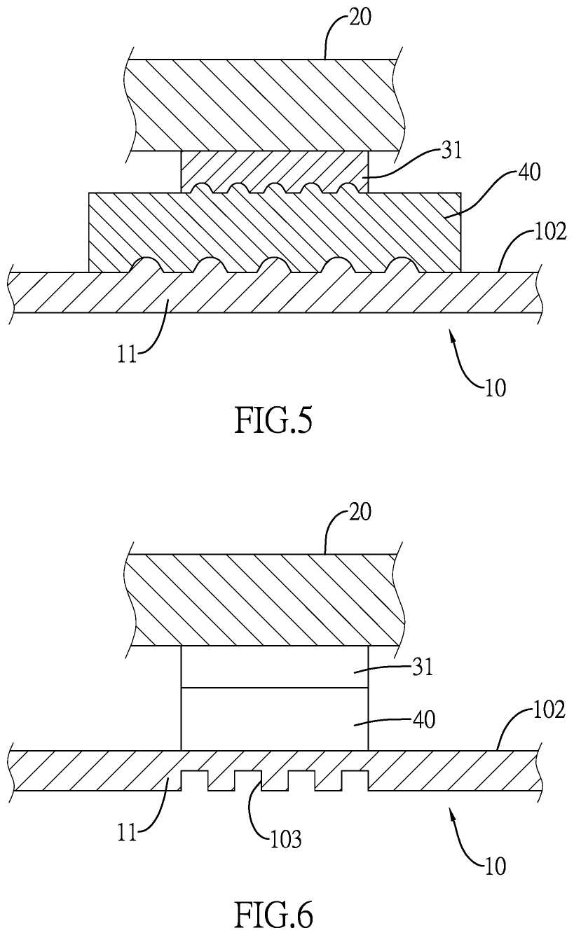

Regarding other embodiments of the present invention that improve the heat conduction and heat dissipation effects of each said power component 31, a connection interface between each said power component 31 and the thermal conductive member 40 can form a concave-convex surface, and/or a connection interface between the thermal conductive member 40 and the inner surface of the heat-dissipation case 10 (and the inner bottom plate surface 102) can also form a concave-convex surface, wherein the surface of each said power component 31 can form a concave-convex surface through common processing means (such as etching, laser engraving, etc.). The concave-convex surface is a non-flat surface, and the concave-convex surface can be, for example, a rough surface, a wavy surface, a zigzag surface, or other patterned uneven surfaces. Therefore, compared with a flat surface, the present invention uses a structure of the concave-convex surface to increase contact area between the thermal conductive member 40, said each of the power components 31, and the heat-dissipation case 10 to improve the heat conduction and heat dissipation effects. In the embodiment shown in FIG. 5, the connection interfaces between the thermal conductive member 40, said each of the power component 31, and the inner bottom plate surface 102 of the heat-dissipation case 10 are concave-convex surfaces.

The present invention can also utilize the structure of the heat-dissipation case 10 to improve the heat dissipation effect; please refer to an embodiment shown in FIG. 6. An outer surface of the heat-dissipation case 10 can be formed into a plurality of channels 103 which pass through a location corresponding to the at least one power component 31. In this way, compared with a completely flat surface, the outer surface of the heat-dissipation case 10 increases the heat dissipation area based on the channels 103 and improves the heat dissipation effect. Furthermore, a fan can be installed outside of the heat-dissipation case 10 so that airflow generated by the fan during operation may carry away the heat of the channels 103 to enhance the heat dissipation effect; or, the heat-dissipation case 10 may be combined with a liquid-cooled heat dissipation device, and the cooling pipes of the liquid-cooled heat dissipation device may be buried in the channels 103 to enhance the heat dissipation effect.

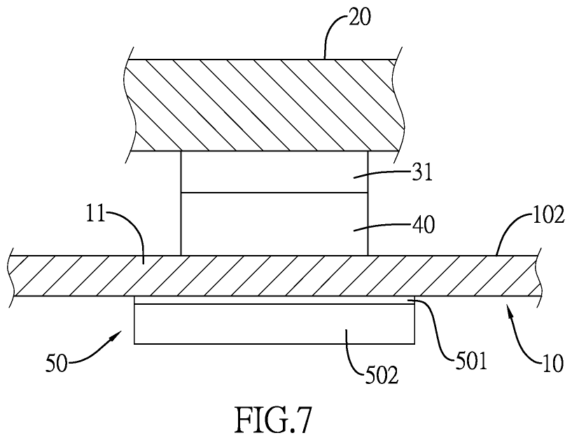

Referring to the embodiment shown in FIG. 7, the outer surface of the heat-dissipation case 10 may be further provided with an exterior heat dissipation member 50 corresponding to a location of the at least one power component 31, so that the heat dissipation effect can be further enhanced by the exterior heat dissipation member 50. Among them, the embodiment of the exterior heat dissipation member 50 may be the embodiments of the thermal conductive member 40 as described above, and will not be repeated herein. Take the example of the exterior heat dissipation member 50 as shown in FIG. 7, which is a composite structure formed by stacking a heat-conducting pad 501 and a metal sheet 502, and the heat-conducting pad 501 is disposed on the outer surface of the heat-dissipation case 10.

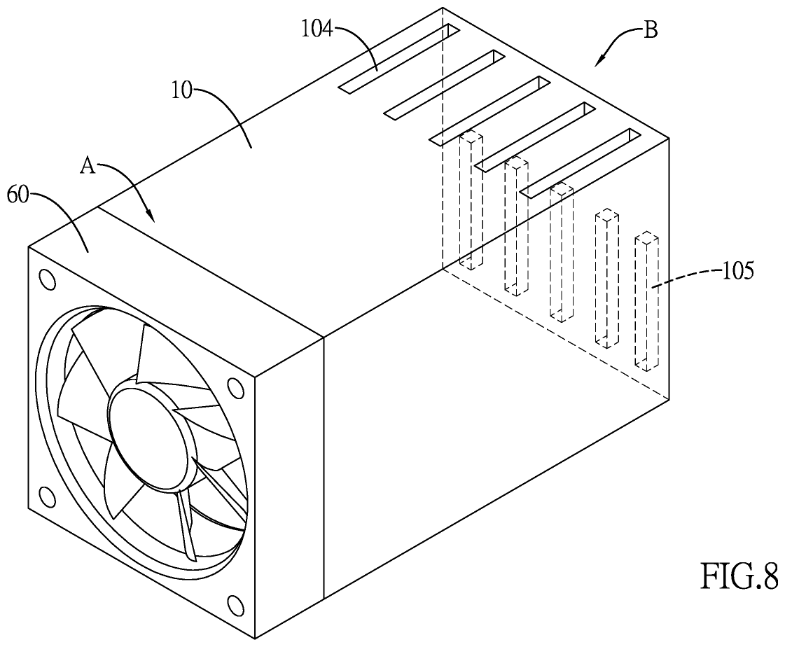

Referring to an embodiment shown in FIG. 8, the heat-dissipation case 10 has a first end A and a second end B, the first end A may be an open end, and the first end A is provided with a ventilator 60, the second end B has a plurality of holes 104 around its peripheral surfaces, and the second end B has a plurality of holes 105 on its end surface. In this way, when the ventilator 60 is in operation, the ventilator 60 can generate a flow of air to draw outside air into the heat-dissipation case 10 through the holes 104, 105 and discharge the air in the heat-dissipation case 10 from the first end A through the ventilator 60; the airflow can take away the heat energy generated by the electronic components 30 in the heat-dissipation case 10 to further improve the heat dissipation effect.

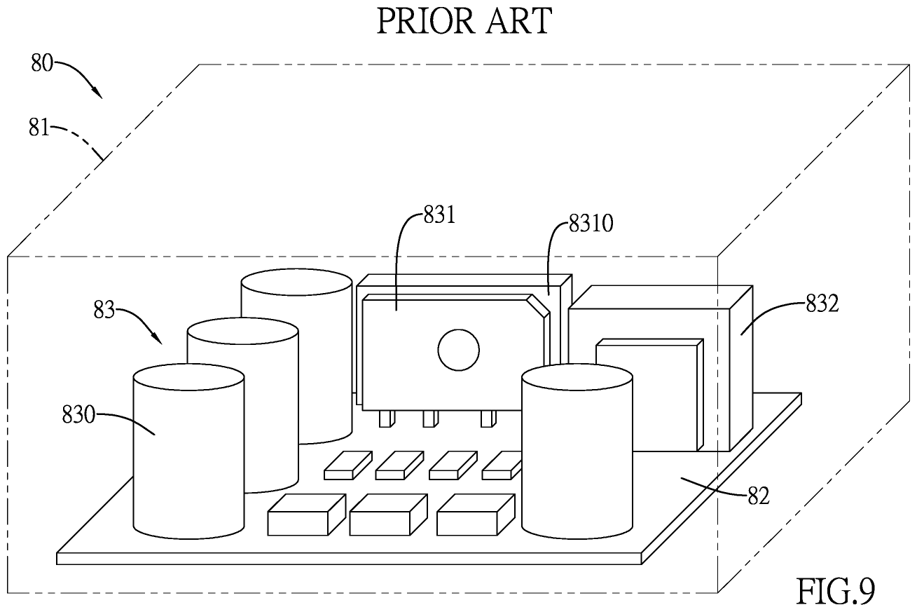

In summary, among the electronic components 30, at least one power component 31 is disposed on the second deployment surface 202 of the circuit board 20, and the other electronic components 30 are located on the first deployment surface 201 of the circuit board 20, which means that not all electronic components 30 of the present invention are disposed on the same side of the circuit board 20; accordingly under the condition of limited space, the first deployment surface 201 of the circuit board 20 has more space for use, thereby improving space utilization. For example, comparing the embodiment of the present invention shown in FIG. 1 with the prior art shown in FIG. 9, under the condition that the circuit boards 20 and 82 have the same size, since the power component 31 of FIG. 1 is disposed on the second deployment surface 202 of the circuit board 20, the first deployment surface of the circuit board 20 of FIG. 1 has more space available for utilization, so that the volume of the transformer 32 can be larger than that of the transformer 832 of FIG. 9 to realize a higher number of turns, or other electronic components can be further disposed to expand functions to meet various customization requirements.

Further, since the at least one power component 31 is connected to the heat-dissipation case 10, and the heat-dissipation case 10 has a heat dissipation function, therefore the heat generated during the operation of the at least one power component 31 may be conducted to the heat-dissipation case 10 to be dissipated, which helps to improve the heat dissipation effect. As previously mentioned, said each power component 31 can be a surface mount device (SMD). Compared with plug-in components, the surface mount component is not erected on the circuit board like the plug-in component. When the surface mount component is installed on the circuit board of the present invention to form a connection, a larger surface area of the surface mount component directly facing the inner bottom plate surface 102 of the heat-dissipation case 10 or the thermal conductive member 40 is helpful for disposition and heat dissipation.

The components and their dimensions, relative proportions, and layout of electronic components disclosed in FIGS. 1 through 9 are presented schematically for reference only.

Although the present invention has been disclosed as above by way of a preferred embodiment, it is not intended to limit the present invention, and any one skilled in the art may make certain changes and modifications without departing from the spirit and scope of the present invention, and therefore the scope of protection of the present invention shall be subject to the scope of the appended patent claims as defined herein.

What is claimed is:

1. A power supply unit with improved space utilization and heat dissipation including:
a heat-dissipation case;
a circuit board, disposed in the heat-dissipation case and having a first deployment surface and a second deployment surface located in opposite positions; and
a plurality of electronic components including at least one power component and other electronic components, wherein the other electronic components are disposed on the first deployment surface of the circuit board, and the at least one power component is disposed on the second deployment surface of the circuit board and connected to an inner surface of the heat-dissipation case.

2. The power supply unit as claimed in claim 1, wherein each said power component is connected to the inner surface of the heat-dissipation case through a thermal conductive member.

3. The power supply unit as claimed in claim 2, wherein the thermal conductive member is a layer of thermal interface material or a metal block.

4. The power supply unit as claimed in claim 2, wherein the thermal conductive member is a composite structure formed by stacking at least two of heat-conducting pads, metal blocks, metal sheets and cooling fins.

5. The power supply unit as claimed in claim 2, wherein a connection interface between each said power component and the thermal conductive member is a concave-convex surface.

6. The power supply unit as claimed in claim 2, wherein a connection interface between the thermal conductive member and the inner surface of the heat-dissipation case is a concave-convex surface.

7. The power supply unit as claimed in claim 5, wherein a connection interface between the thermal conductive member and the inner surface of the heat-dissipation case is a concave-convex surface.

8. The power supply unit as claimed in claim 2, wherein each said power component is embedded into the thermal conductive member.

9. The power supply unit as claimed in claim 1, wherein an outer surface of the heat-dissipation case is provided with an outer heat dissipation member corresponding to a location of the at least one power component.

10. The power supply unit as claimed in claim 1, wherein the heat-dissipation case has a first end and a second end, the first end is provided with a ventilator, and the second end has a plurality of holes.

11. The power supply unit as claimed in claim 1, wherein an outer surface of the heat-dissipation case has a plurality of channels which pass through a location corresponding to the at least one power component.
